(19) United States
(12) Patent Application Publication
(10) Pub. No.: US 2016/0148875 A1
(43) Pub. Date: May 26, 2016

(54) SEMICONDUCTOR ELEMENT SUBSTRATE, AND METHOD FOR PRODUCING SAME

(71) Applicant: SHARP KABUSHIKI KAISHA, Osaka (JP)

(72) Inventors: Tomoaki OKAMOTO, Osaka-shi (JP); Masahiko YANAGI, Osaka-shi (JP); Tomomi KAWAKAMI, Osaka-shi (JP)

(21) Appl. No.: 14/906,006

(22) PCT Filed: Jun. 26, 2014
(86) PCT No.: PCT/JP2014/003426

§ 371 Date: Jan. 19, 2016

(30) Foreign Application Priority Data
Aug. 8, 2013 (JP) 2013-165615

(51) Int. Cl. H01L 23/544

(52) U.S. Cl. CPC H01L 23/544; H01L 2223/5446

(57) ABSTRACT

A diffusion time when forming an isolation region is shortened without deteriorating strength against wafer cracks. A plurality of circular holes 4a and 4b are respectively provided side by side on both surfaces of the wafer discontinuously and intermittently along a scribe line SL between semiconductor devices which are adjacent to each other, and isolation diffusion layers 5a and 5b in a single conductivity type (here, P-type) used for element isolation are respectively formed around the plurality of circular holes 4a and 4b so as to reach a center portion in a depth direction from the both surfaces of the wafer and to be at least partially overlapped with each other between adjacent holes and between upper and lower bottom surfaces.

### TECHNICAL FIELD

The present invention relates to a semiconductor element substrate with an isolation diffusion layer formed by using an isolation technique for element isolation, and a method for producing the same.

### BACKGROUND ART

As an isolation technique in a conventional semiconductor element substrate and a method for producing the same, for example, a diffusion layer is formed as an element isolation insulating structure, in addition to LOCOS and STI. In the isolation diffusion layer, an impurity is implanted into a semiconductor layer from three directions of a front surface, and a side surface and a bottom surface of a groove, so that the impurity is able to be implanted into a deeper region through the formed groove. Thereby, it is possible to significantly shorten a diffusion time for diffusing the impurity to a given diffusion region by performing heating processing after ion-implantation of the impurity.

In this manner, for diffusion for the isolation diffusion layer which needs to be formed deeply in order to perform element isolation between semiconductor chips and between semiconductor devices, the impurity is ion-implanted from three directions of a front surface of a semiconductor substrate, a side surface and a bottom surface of the groove which is formed before the diffusion, and is diffused. Since the impurity is able to be ion-implanted to a deeper region corresponding to a depth of the formed groove, it is possible to form the diffusion layer used for element isolation at a predetermined depth in a significantly short time.

Thus, the groove which is formed in advance allows significant shortening of the diffusion time in the high temperature atmosphere, thus also making it possible to prevent an abnormal reaction between an insulating film and the impurity. Therefore, an effect that surface abnormalities such as a pin-hole are prevented from being caused in the semiconductor substrate and a withstand voltage and a yield of production are improved is also achieved. This is proposed in PTL 1 by exemplifying a method for producing a thyristor as a conventional method for producing a semiconductor device.

FIG. 13(a) to FIG. 13(e) are schematic vertical cross-sectional views illustrating a conventional process for producing a thyristor, which is disclosed in PTL 1, in the order of steps.

In the conventional process for producing a thyristor, as illustrated in FIG. 13(a), first, an insulating film is formed entirely on a front surface alone of an N-type silicon substrate 101, portions corresponding to isolation regions and base regions of the insulating film are removed to form insulating films 102, and the front surface of the N-type silicon substrate 101 is partially exposed.

Next, as illustrated in FIG. 13(b), grooves 103 having a predetermined width and a predetermined depth are formed at portions corresponding to the isolation regions of the exposed N-type silicon substrate 101 along a scribe line.

In the formation of the grooves 103, by dicing or etching, the grooves 103 having a line shape are formed at a predetermined depth from the front surface of the N-type silicon substrate 101 at the portions corresponding to the isolation regions of the N-type silicon substrate 101, that is, on the scribe line.

Subsequently, as illustrated in FIG. 13(c), with the insulating films 102 on the front surface of the N-type silicon substrate 101 as a mask, an impurity is implanted from a front surface side and a rear surface side of the N-type silicon substrate 101 simultaneously and then diffusion of the impurity is performed, so that P-type isolation diffusion layers 104 around the grooves 103, P-type base diffusion layers 105, and a P-type anode diffusion layer 106 which is connected to the P-type isolation diffusion layers 104 are formed simultaneously.

That is, the N-type silicon substrate 101 in which the grooves 103 are formed is placed in a diffusion furnace, and with the insulating films 102 as a mask as illustrated in FIG. 13(c), diffusion is performed after implanting a P-type dopant, for example, such as boron, the P-type isolation diffusion layers 104 are formed deeply in the N-type substrate 101, the P-type base diffusion layers 105 are formed on a surface layer portion of the N-type silicon substrate 101, and the P-type anode diffusion layer 106 is formed on the rear surface side of the N-type silicon substrate 101.

Note that, temperature in the diffusion furnace is preferably 1200 to 1300 degrees centigrade. A diffusion time is set to a time to an extent that, at least, the P-type isolation diffusion layers 104 for element isolation are formed deeply in the N-type silicon substrate 101 and the P-type isolation diffusion layers 104 and the P-type anode diffusion layer 106 are connected vertically.

Thereafter, as illustrated FIG. 13(d), the insulating films 102 used as the mask are removed, and insulating films 107 composed of SiO₂ are newly formed only on the front surface of the N-type silicon substrate 101. Further, with a photolithography technique, portions corresponding to cathode regions of the insulting films 107 are removed, and opening portions are subjected to patterning so as to partially expose the front surface of the N-type silicon substrate 101.

Subsequently, the N-type silicon substrate 101 is placed in the diffusion furnace, and an N-type dopant, for example, such as phosphorus is implanted with the insulating films 107 as a mask, and then subjected to heating processing and diffusion, so that N-type cathode diffusion layers 108 are formed in the P-type base diffusion layers 105.

Further, as illustrated in FIG. 13(e), with the photolithography technique, the insulating films 107 on the N-type cathode diffusion layers 108 and the P-type base diffusion layers 105 are removed, and contact holes 109 and 110 are respectively formed on the N-type cathode diffusion layers 108 and the P-type base diffusion layers 105. A conductive substance such as metal is deposited in each of the contact holes 109 and 110, for example, by PVD or the like, and an anode electrode 111 is formed on the P-type anode diffusion layer 106 on the rear surface.

Cathode electrodes 112 are formed on the N-type cathode diffusion layers 108 so as to be connected and gate electrodes 113 are formed on the P-type base diffusion layers 105 so as to be connected.

Finally, by performing dicing along the scribe line SL and dividing into individual semiconductor chips, each thyristor 100 is able to be obtained.

### CITATION LIST

### Patent Literature

PTL 1: Japanese Unexamined Patent Application Publication No. 7-235660

### SUMMARY OF INVENTION

### Technical Problem

With the conventional method for producing the thyristor 100, which is disclosed in PTL 1, before forming the P-type isolation diffusion layers 104, the P-type base diffusion layers 105, and the P-type anode diffusion layer 106, the grooves 103 having the predetermined depth from the front surface of the N-type silicon substrate 101 are formed at portions corresponding to the isolation regions of the N-type silicon substrate 101 at the step of FIG. 13(b). Thereby, in diffusion of the P-type isolation diffusion layers 104 which need to be formed deeply for element isolation, the diffusion is performed by heating processing after ion-implantation of a P-type impurity from three directions of a front surface 101a of the N-type silicon substrate 101, a side wall 103a and a bottom surface 103b of each of the grooves 103 as illustrated in FIG. 14, so that vertical connection between the P-type isolation diffusion layers 104 and the P-type anode diffusion layer 106 is established and element isolation between adjacent thyristors is able to be performed in a relatively short diffusion time.

However, in the conventional method for producing thyristors, by using dicing or etching steps, the consecutive grooves 103 having the line shape are formed at the predetermined depth from the front surface of the N-type silicon substrate 101 at the portions corresponding to the isolation regions of the N-type silicon substrate 101, for example, on the scribe line SL, by which the grooves 103 become etched lines to cause reduction in margin for stress and cracks may occur in the wafer in a producing step due to stress of films or the like, for example, because of vibration at a time of conveying a substrate or the like, particularly, in a semiconductor wafer whose thickness of a semiconductor wafer is small, for example, 245 μm. Further, since the grooves are processed from one direction of only the front surface of the substrate, further shortening of the diffusion time when forming the isolation regions used for element isolation is limited and the method is not suitable for a thick wafer.

The invention is made for solving the aforementioned conventional problem and an object thereof is to provide a semiconductor element substrate and a method for producing the same capable of shortening a diffusion time when forming isolation regions without deteriorating strength against wafer cracks.

### Solution to Problem

The invention provides a semiconductor element substrate, in which a plurality of semiconductor devices are arranged in a matrix manner, a plurality of holes are provided discontinuously along a scribe line between the semiconductor devices which are adjacent to each other, and isolation diffusion layers used for element isolation are respectively formed around the plurality of holes, and thereby the aforementioned object is achieved.

Moreover, it is preferable that the plurality of holes are formed along the scribe line from both surfaces of the substrate, and the respective isolation diffusion layers in a single conductivity type used for the element isolation are formed so as to reach a center portion in a depth direction from the both surfaces of the substrate and to be at least partially overlapped with each other between adjacent holes and vertically, in the semiconductor element substrate of the invention.

Further, it is preferable that a plurality of holes aligned with a pitch in the front surface of the substrate are shifted with respect to a plurality of holes formed in the rear surface of the substrate, in a method for producing the semiconductor element substrate of the invention.

Further, it is preferable that a distance of a connected portion between the adjacent holes which are adjacent in a direction of the scribe line and a distance in a depth direction between a bottom surface of each of the holes in the front surface of the substrate and a bottom surface of each of the holes in the rear surface of the substrate are the same, in the method for producing the semiconductor element substrate of the invention.

Further, it is preferable that each shape of a plurality of holes is any of a circular shape, an oval shape, and a rectangular shape in a plan view in the method for producing the semiconductor element substrate of the invention.

A method for producing a semiconductor element substrate of the invention includes: a hole formation step of forming a plurality of holes, which are discontinuous, along a scribe line on one surface or both surfaces of the substrate; an impurity implantation step of ion-implanting an impurity from both surfaces of a wafer through the holes to form an impurity region; an isolation diffusion step of diffusing the impurity by heating processing to form isolation diffusion layers; and a semiconductor device formation step of forming a semiconductor device (a semiconductor device including a semiconductor element) for each element isolation region surrounded by the isolation diffusion layers, and thereby the aforementioned object is achieved.

With the configurations above, effects of the invention will be described below.

In the invention, a plurality of semiconductor devices are arranged in a matrix manner, a plurality of holes are provided discontinuously along a scribe line between the semiconductor devices which are adjacent to each other, and isolation diffusion layers used for element isolation are respectively formed around the plurality of holes.

This makes it possible to shorten a diffusion time when forming isolation regions without deteriorating strength against wafer cracks.

### Advantageous Effects of Invention

Accordingly, with the invention, it is possible to shorten a diffusion time when forming isolation regions without deteriorating strength against wafer cracks.

### BRIEF DESCRIPTION OF DRAWINGS

FIG. 1 is a plan view schematically illustrating a semiconductor wafer as a semiconductor element substrate in Embodiment 1 of the invention.

FIG. 2 is an enlarged plan view of two chips in the semiconductor wafer of FIG. 1.

FIG. 3 is a cross-sectional view taken along an A-A line in FIG. 2.

FIG. 4 is an enlarged cross-sectional view of two adjacent circular holes and isolation diffusion layers therearound on both surfaces of the semiconductor wafer, and (a) is an enlarged cross-sectional view of a semiconductor wafer of Embodiment 1 of the invention, in which holes in the front surface are aligned so as to oppose respective holes aligned with a uniform pitch in the rear surface, and (b) is an enlarged cross-sectional view of a semiconductor wafer of Embodiment 2 of the invention, in which the holes aligned in the front surface are shifted by half of the pitch with respect to the holes aligned in the rear surface.

FIG. 5 is a view illustrating a relationship of a diffusion time to a center-to-center distance (pitch P1) between the circular holes of FIG. 4.

FIG. 6 is a view illustrating a relationship of the diffusion time to a hole depth of the circular holes of FIG. 4.

FIG. 7 is a characteristics view illustrating a relationship of a diffusion time to a hole depth on one side when holes are formed on both surfaces.

FIG. 8 is an enlarged plan view of two adjacent chips in a semiconductor wafer as a semiconductor element substrate 1B of Embodiment 3 of the invention.

FIGS. 9(a) and (b) are vertical cross-sectional views illustrating isolation steps of a process for producing a chip in a semiconductor element substrate of Embodiment 4 of the invention.

FIGS. 10(a) and (b) are vertical cross-sectional views illustrating boron diffusion and phosphorus diffusion steps of the process for producing the chip in the semiconductor element substrate of Embodiment 4 of the invention.

FIGS. 11(a) and (b) are vertical cross-sectional views illustrating a film growth step by CVD and an electrode formation step of the process for producing the chip in the semiconductor element substrate of Embodiment 4 of the invention.

FIGS. 12(a) and (b) are vertical cross-sectional views illustrating rear surface electrode formation and PI coat formation steps of the process for producing the chip in the semiconductor element substrate of Embodiment 4 of the invention.

FIGS. 13(a) to (e) are schematic vertical cross-sectional views illustrating a conventional process for producing a thyristor, which is disclosed in PTL 1, in the order of steps.

FIG. 14 is an enlarged vertical cross-sectional view of a groove and a peripheral portion of the groove when a P-type isolation diffusion layer is formed.

### REFERENCE SIGNS LIST

1, 1A, 1B semiconductor element substrate
2 orientation flat
3 semiconductor chip
SL scribe line
4a, 4b circular hole
5a, 5b isolation diffusion layer
6a, 6b oval hole
7a, 7b isolation diffusion layer
11 semiconductor wafer (N-type substrate)
12a, 12b first oxide insulating film
13a, 13b second oxide insulating film
14 front surface-side P-type diffusion layer
15 rear surface-side P-type diffusion layer
16, 17 front surface-side N-type diffusion layer
18 rear surface-side N-type diffusion layer
19 CVD film
20 PI coat film

### DESCRIPTION OF EMBODIMENTS

Description will hereinafter be given in detail for Embodiments 1 to 4 of a semiconductor element substrate and a method for producing the same of the invention with reference to drawings. Note that, from a viewpoint of creating the drawings, thickness and length of each constituent member or the like in each drawing are not limited to the illustrated configuration. In addition, for example, a diameter, a depth, a pitch P, and the number of holes may not be identical to those of an actual device, but the diameter, the depth, the pitch P, and the number of holes are obtained in consideration of convenience of illustration and description and not limited to the illustrated configuration. Further, Embodiments 1 to 4 of the semiconductor element substrate and the method for producing the same of the invention can be modified variously within the scope indicated in the claims. That is, embodiments obtained by further combining technical means modified appropriately within the scope indicated in the claims are also included in the technical scope of the invention.

### Embodiment 1

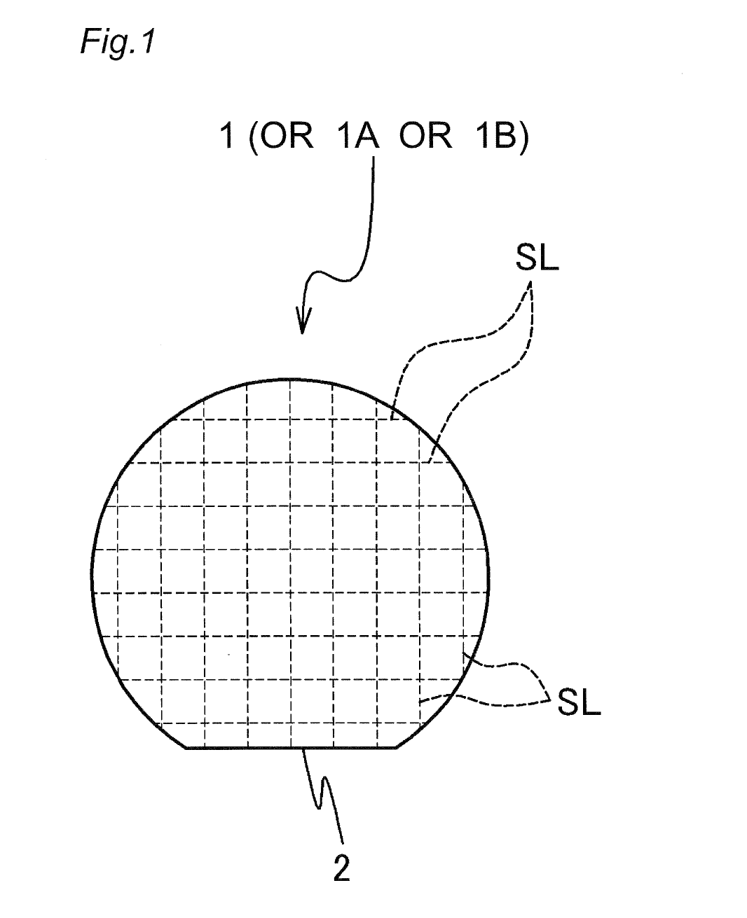

FIG. 1 is a plan view schematically illustrating a semiconductor wafer as a semiconductor element substrate in Embodiment 1 of the invention.

In FIG. 1, a semiconductor element substrate 1 of Embodiment 1 here is composed of a semiconductor wafer having a circular shape in a plan view. The semiconductor wafer as the semiconductor element substrate 1 has an orientation flat 2 formed as a flat portion for indicating a direction thereof. In the semiconductor wafer, a plurality of semiconductor chips 3 are arranged in a matrix manner as a plurality of semiconductor devices, and a scribe line SL indicated with the dotted line is provided vertically and horizontally between the semiconductor devices which are adjacent to each other so that the scribe line SL is formed in a grid manner over the entire wafer. The scribe line SL is a line for dividing into individual semiconductor devices by dicing.

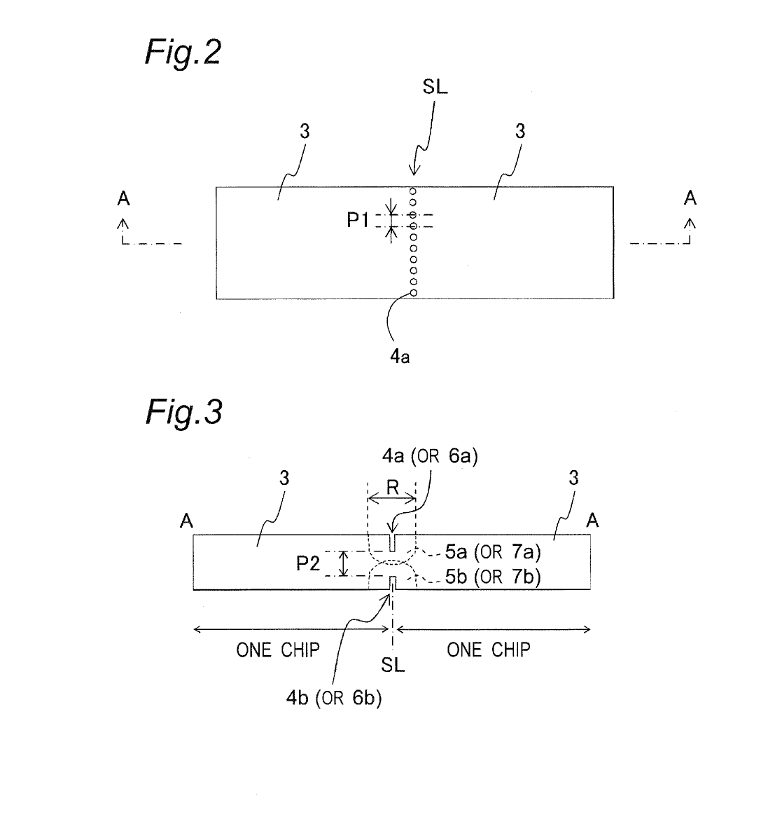

In the semiconductor element substrate 1 of Embodiment 1, on each of both surfaces of the wafer, a plurality of holes are provided side by side discontinuously and intermittently along the scribe line SL between the semiconductor devices which are adjacent to each other, and isolation diffusion layers in a single conductivity type used for element isolation are respectively formed around the plurality of holes. This will be described in detail with following FIG. 2 and FIG. 3.

FIG. 2 is an enlarged plan view of two adjacent chips in the semiconductor wafer of FIG. 1. FIG. 3 is a cross-sectional view taken along an A-A line in FIG. 2.

In FIG. 2 and FIG. 3, between the semiconductor chips 3 serving as the two adjacent chips, circular holes 4a and 4b having a predetermined depth are formed at a predetermined pitch in line in a dot shape (in a discontinuous manner) on the both surfaces of the wafer along the scribe line SL. The circular holes 4a and 4b are formed to have a diameter equal to or smaller than (for example, 40 μm) a dicing width (for example, 60 μm), and when described as a range, from 40 μm to 60 μm.

Respective pitches P1 of the circular holes 4a and 4b are formed to be equal. The adjacent semiconductor chips 3 are connected by a portion between the adjacent circular holes 4a on the front surface side and a portion between the adjacent circular holes 4b on the rear surface side. Thus, a configuration resistant to wafer cracks due to stress is provided.

Since the circular holes 4a and 4b having the predetermined depth are formed along the straight line in the dot shape on the both surfaces of the wafer in this manner, each of the circular holes 4a and 4b on the both surface sides reaches a vicinity of a deep center position of wafer thickness, so that a diffusion time to a given region in which the isolation diffusion layers 5a and 5b used for element isolation are connected vertically is shortened significantly.

The respective upper and lower isolation diffusion layers 5a and 5b are thermally diffused by heating processing after, for example, a P-type impurity is ion-implanted from three directions of the front surface of a silicon substrate of the semiconductor wafer, and the side wall and the bottom surface of each of the circular holes 4a and 4b. Thereby, in a relatively short time, through the plurality of circular holes 4a and 4b in the dot shape on the both surface sides of the wafer along the scribe line SL, borders between the isolation diffusion layers 5a and 5b are respectively overlapped from front and back and from up and down between the adjacent holes which are arranged in front and back and between bottom surfaces of the adjacent upper and lower holes, and element isolation is carried out more reliably.

In short, the circular holes 4a and 4b are respectively formed along the scribe line SL from the both surfaces of the substrate, and the respective isolation diffusion layers 5a and 5b in a single conductivity type (here, P-type) used for element isolation are formed so as to reach the center portion in a depth direction from the both surfaces of the substrate through the circular holes 4a and 4b and to be overlapped with each other by reaching the portion between the adjacent holes and the portion between the bottom surfaces of the upper and lower holes.

The respective isolation diffusion layers 5a and 5b are diffused being spread, for example, with a diameter R with the circular holes 4a and 4b on the both surface sides of the wafer, which are arranged in line, as centers. Accordingly, a distance of a connected portion obtained by subtracting a hole diameter from a center-to-center distance (pitch P1) between the circular holes 4a or 4b on either of the both surfaces of the wafer and a distance in a depth direction between the respective bottom surfaces of the circular holes 4a and 4b (P2) are preferably set to be equal. In short, the distance of the connected portion between the respective circular holes 4a and 4b which are adjacent in the direction of the scribe line SL and the distance between the bottom surface of the circular hole 4a on the front surface of the wafer and the bottom surface of the circular hole 4b on the rear surface of the wafer are set to be the same.

If the distance obtained by subtracting the hole diameter from the center-to-center distance between the circular holes 4a or 4b (pitch P1) and the distance in the depth direction between the respective bottom surfaces of the circular holes 4a and 4b (P2) are equal in this manner, when the isolation diffusion layers 5a and 5b have diffusion regions spread from the circular holes 4a and 4b, the isolation diffusion layers 5a and 5b which are adjacent to each other reach each other from front and back and from up and down and are then overlapped with each other with the almost same extent at the almost same time, thus making it possible to set the diffusion time efficiently.

Thus, according to Embodiment 1, the plurality of circular holes 4a and 4b are respectively provided on the both surfaces of the wafer side by side discontinuously and intermittently along the scribe line SL between the semiconductor devices which are adjacent to each other, and the isolation diffusion layers 5a and 5b in a single conductivity type (here, P-type) used for element isolation are respectively formed around the plurality of circular holes 4a and 4b so as to reach the center portion in the depth direction from the both surfaces of the wafer and to be at least partially overlapped with each other between the adjacent holes and between the upper and lower bottom surfaces.

Thereby, the isolation diffusion layers 5a and 5b are respectively formed simultaneously from the both surface sides of the wafer through the plurality of circular holes 4a and 4b having the predetermined depth on the both surfaces of the wafer, which are formed side by side intermittently in the dot shape, so that it is possible to obtain the semiconductor wafer as the semiconductor element substrate 1 of Embodiment 1 capable of shortening the diffusion time when forming the isolation regions without deteriorating strength against wafer cracks compared to a conventional case using grooves having a line shape. It is possible to easily cut the semiconductor wafer along the scribe line SL from the plurality of circular holes 4a and 4b in the dot shape to divide into a plurality of semiconductor element chips.

Note that, Embodiment 1 describes a case where at positions of element isolation in the scribe line SL, the plurality of circular holes 4a and 4b having the predetermined depth are formed on the both surfaces of the wafer at the predetermined pitch in line in the dot shape (in a discontinuous manner), and then, the isolation diffusion layers 5a and 5b are respectively formed from the both surface sides of the wafer through the circular holes 4a and 4b having the predetermined depth on the both surfaces of the wafer, but without limitation thereto, it may be configured such that at positions of element isolation in the scribe line SL, the circular holes 4a having the predetermined depth are formed at the predetermined pitch in line in the dot shape (in a discontinuous manner) only on the front surface (one side) of the wafer, and then, the isolation diffusion layers 5a and the like are formed from the both surface sides of the wafer through only the circular holes 4a having the predetermined depth on the front surface side. In this case, the isolation diffusion layers 5b are not provided deeply as much as the circular holes 4b having the predetermined depth on the rear surface side are not involved, and the diffusion time becomes long, but the strength against wafer cracks is further kept, for example, when a semiconductor wafer is thin.

### Embodiment 2

Though the case where the respective pitches of the circular holes 4a and 4b formed on the both surfaces of the semiconductor wafer are not shifted to each other has been described in Embodiment 1 above, a case where the respective pitches of the circular holes 4a and 4b formed on the both surfaces of the semiconductor wafer are shifted to each other by half a pitch successively will be described in Embodiment 2.

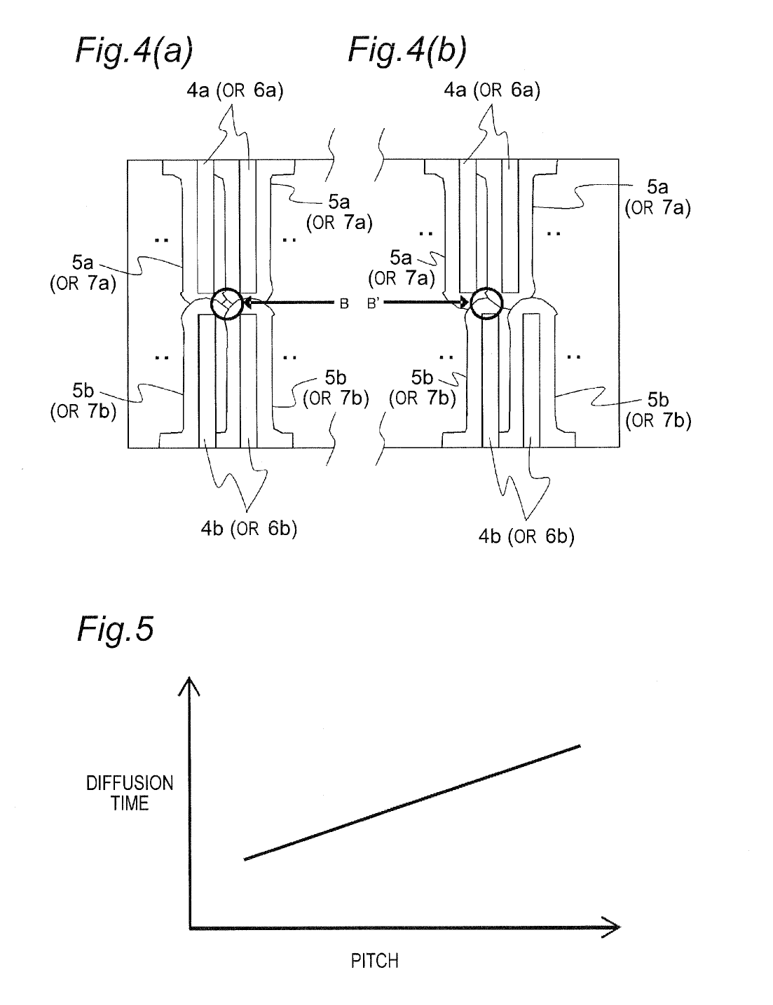

FIG. 4 is an enlarged cross-sectional view of two adjacent circular holes 4a and 4b and isolation diffusion layers 5a and 5b therearound on both surfaces of a semiconductor wafer as a semiconductor element substrate 1A of Embodiment 2 of the invention, and FIG. 4(a) is an enlarged cross-sectional view of a semiconductor wafer of Embodiment 1 of the invention, in which holes in the front surface are aligned so as to oppose respective holes aligned with a uniform pitch in the rear surface, and FIG. 4(b) is an enlarged cross-sectional view of a semiconductor wafer of Embodiment 2 of the invention, in which the holes aligned in the front surface are shifted by half of the pitch with respect to the holes aligned in the rear surface of the semiconductor wafer of Embodiment 2 of the invention. Note that, in FIG. 4(a) and FIG. 4(b), description will be given by assigning the same reference signs to members which exert the same effects as the effects of the constituent members described in FIG. 1 to FIG. 3.

The diffusion time is able to be further shortened when the positions at which the holes are formed are shifted between the front surface of the wafer and the rear surface of the wafer in FIG. 4(a) and FIG. 4(b). This provides states of the isolation diffusion layers 5a and 5b, for example, after 100 minutes have passed, in which an impurity concentration is 1×10²¹ cm⁻³, and temperature is 1250 degrees centigrade.

This will be described below in detail.

The respective two adjacent circular holes 4a and 4b which are taken from the both surfaces of the semiconductor wafer and the isolation diffusion layers 5a and 5b therearound are illustrated. As to a difference between FIG. 4(a) and FIG. 4(b), in FIG. 4(a), the pitch P1 of the two adjacent circular holes 4a and 4a which are taken from the front surface of the semiconductor wafer and the pitch P1 of the two adjacent circular holes 4b and 4b facing thereto, which are taken from the rear surface of the semiconductor wafer, are not shifted to each other, and the respective bottom surfaces of the circular holes 4b and 4b are positioned at positions directly under the respective bottom surfaces of the circular holes 4a and 4a. On the other hand, in FIG. 4(b), the pitch P1 of the two adjacent circular holes 4a and 4a which are taken from the front surface of the semiconductor wafer and the pitch P1 of the two adjacent circular holes 4b and 4b facing thereto, which are taken from the rear surface of the semiconductor wafer, are shifted by half a pitch, and the bottom surface of the circular hole 4b is positioned at a position directly under a position between the respective bottom surfaces of the circular holes 4a and 4a which are horizontally arrayed. In short, the formation is provided in such a manner that the pitch P1 of the circular hole 4a which is formed from the front surface of the wafer and the pitch p1 of the circular hole 4b which is formed from the rear surface of the wafer are shifted to each other by half a pitch.

In this manner, the circular holes 4a and 4b having the predetermined depth are formed at the predetermined pitch in the dot shape (in a discontinuous manner) on the front surface and the rear surface of the wafer along the scribe line SL, in which the plurality of circular holes 4a which are arrayed on the front surface side of the wafer and the plurality of circular holes 4b which are arrayed on the rear surface side of the wafer are formed so that the circular holes 4a and 4b having the predetermined depth are shifted to each other by half a pitch in a direction along the scribed line SL. The isolation diffusion layers 5a and 5b are formed around the respective circular holes 4a and 4b, in which positions of the diffusion layers at the deepest positions correspond to the bottom surfaces of the circular holes 4a and 4b, and diffusion regions continue obliquely and roundly from the positions of the isolation diffusion layers 5a and 5b at the deepest positions to the positions of the isolation diffusion layers 5a and 5b corresponding to side surfaces of the circular holes 4a and 4b, so that when the pitches 1 of the adjacent circular holes 4a on the front surface side and the adjacent circular holes 4b facing thereto on the rear surface side are not shifted, a region B of FIG. 4(a) which is not diffused and has a hole exists between a valley of a diffusion region between the adjacent circular holes 4a on the front surface side and a valley of a diffusion region between the adjacent circular holes 4b facing thereto on the rear surface side. Sufficient element isolation is not performed for adjacent elements through the region B which is not diffused. Therefore, the diffusion time for eliminating the region B which has the hole by further diffusing the isolation diffusion layers 5a and 5b by further performing heating processing becomes required. On the other hand, when the pitches of the adjacent circular holes 4a on the front surface side and the adjacent circular holes 4b facing thereto in a vertical direction on the rear surface side are shifted by half a pitch, it is unnecessary to perform further heating processing, and the region B of FIG. 4(a) which has the hole is eliminated, so that a region B′ of FIG. 4(b) whose hole is closed by the diffusion layers is provided. Thereby, the required diffusion time may be further shortened.

FIG. 5 is a view illustrating a relationship of a diffusion time to a center-to-center distance (pitch P1) between the circular holes 4a or 4b of FIG. 4.

As illustrated in FIG. 5, as the pitch P1 which is a center-to-center distance between the adjacent circular holes 4a or the pitch P1 which is a center-to-center distance between the adjacent circular holes 4b increases, a region in which diffusion of the isolation diffusion layers 5a and 5a which are adjacent on the upper side and a region in which diffusion of the isolation diffusion layers 5b and 5b which are adjacent on the lower side spread, so that the diffusion time increases. The isolation diffusion layer 5a and 5b are respectively diffused in the vertical direction and in the arrangement direction by heating processing and the isolation diffusion layers 5a and 5b are overlapped in the vertical and arrangement directions as an impurity region, so that element isolation is performed more reliably between element chips.

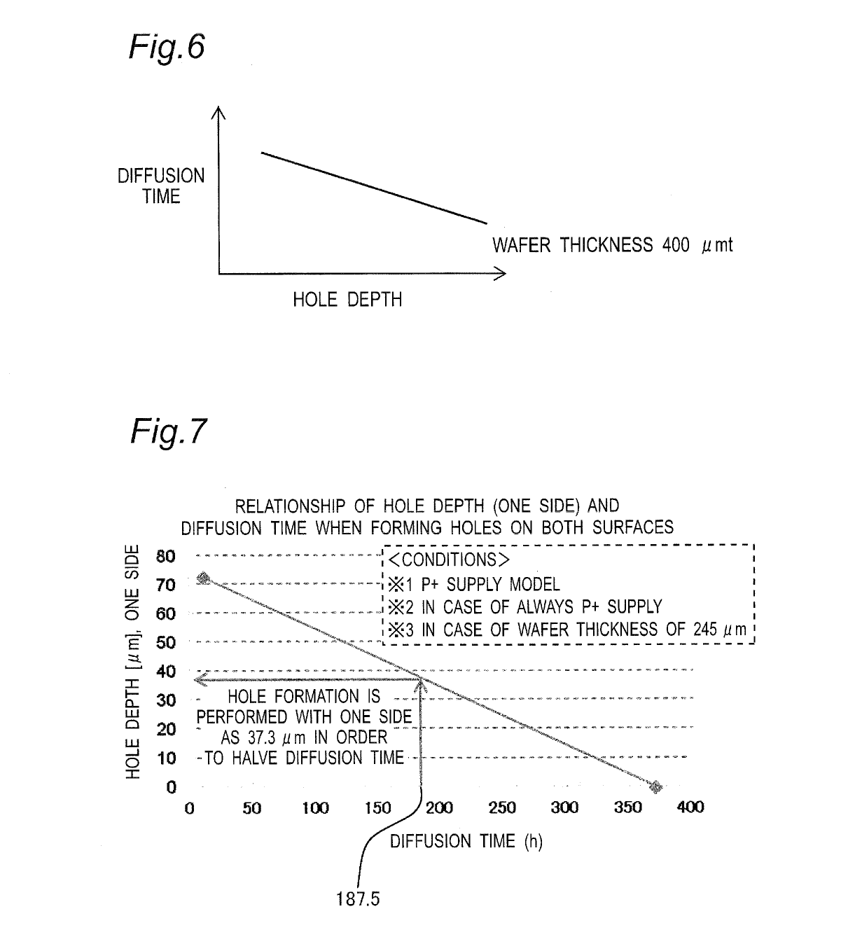

FIG. 6 is a view illustrating a relationship of the diffusion time to a hole depth of the circular holes 4a and 4b of FIG. 4.

As illustrated in FIG. 6, as each hole depth of the circular holes 4a and 4b becomes deep, a distance in a depth direction between the respective bottom surfaces of the circular holes 4a and 4b (P2 in FIG. 3) becomes short, so that the diffusion time is reduced.

It is required that by heating processing, the isolation diffusion layers 5a and 5b are diffused in the respective vertical and hole arrangement directions, and reached each other, and the isolation diffusion layers 5a and 5b are overlapped in the respective vertical and hole arrangement directions as the impurity region, so that element isolation is performed more reliably between element chips.

Accordingly, as the diffusion time, it is desired that a distance of a connected portion obtained by subtracting the hole diameter from the center-to-center distance between the circular holes 4a or 4b (pitch P1 of FIG. 2) and a distance in the depth direction between the respective bottom surfaces of the circular holes 4a and 4b (P2 of FIG. 3) are the same because the most excellent efficiency is achieved and the time becomes the shortest. When the respective hole depths of the circular holes 4a and 4b are made deeper, the distance in the depth direction between the respective bottom surfaces of the circular holes 4a and 4b (P2 of FIG. 3) becomes short, and the respective pitches P1 of the circular holes 4a and 4b are also reduced according to the distance in the depth direction of the circular holes 4a and 4b (P2 of FIG. 3). In a case where the distance obtained by subtracting the hole diameter from the center-to-center distance between the circular holes 4a or 4b (pitch P1) and the distance in the depth direction between the respective bottom surfaces of the circular holes 4a and 4b (P2) are the same, when the isolation diffusion layers 5a and 5b spread from peripheries of the circular holes 4a and 4b, the isolation diffusion layers 5a and 5b which are adjacent to each other are stuck and then overlapped with each other, so that element isolation is ensured.

FIG. 7 is a characteristics view illustrating a relationship of a diffusion time to a hole depth on one side when holes are formed on the both surfaces.

As illustrated in FIG. 7, in a relationship of the diffusion time to each hole depth on one side when holes are formed on the both surfaces in which wafer thickness is 245 μm, when each depth of the circular holes 4a and 4b is 70 μm, the diffusion time requires 10 hours, and when each depth of the circular holes 4a and 4b is 0 μm, that is, when no hole is provided, 375 hours are required for sticking the respective isolation diffusion layers from the both surfaces of the wafer. When the diffusion is performed by heating processing for 187.5 hours as half the 375 hours, each depth of the circular holes 4a and 4b needs 37.3 μm.

Accordingly, with Embodiment 2, the plurality of circular holes 4a and 4b are respectively formed along the scribe line SL from the both surfaces of the wafer, and the respective P-type isolation diffusion layers 5a and 5b used for element isolation are formed so as to reach the center portion in the depth direction from the both surfaces of the wafer and to be at least partially overlapped with each other between the adjacent holes and vertically. In this case, the formation is provided in such a manner that the pitch P1 of the plurality of circular holes 4a formed from the front surface of the wafer and the pitch P1 of the plurality of circular holes 4b formed from the rear surface of the wafer are not the same, but shifted to each other (for example, by half a pitch).

Thereby, since the isolation diffusion layers 5a and 5b are formed from the both surface sides by shifting formation pitches of the circular holes 4a and 4b having the predetermined depth on the both surfaces of the wafer are shifted to each other, the respective isolation diffusion layers 5a and 5b are formed efficiently and it is possible to obtain the semiconductor wafer as the semiconductor element substrate 1A of Embodiment 1 capable of significantly shortening the diffusion time when forming the isolation regions without deteriorating strength against wafer cracks. It is possible to perform cutting through the circular holes 4a and 4b in the dot shape along the scribe line SL of the semiconductor wafer to divide into a plurality of semiconductor element chips.

### Embodiment 3

Though the case where the circular holes 4a and 4b having bottoms are formed on the both surfaces of the semiconductor wafer has been described in Embodiments 1 and 2 above, described in Embodiment 3 is a case where oval holes are formed on the both surfaces of the semiconductor wafer, and examples of holes having shapes other than the circular shape of the circular holes 4a and 4b include oval holes and rectangular holes (a square or an oblong).

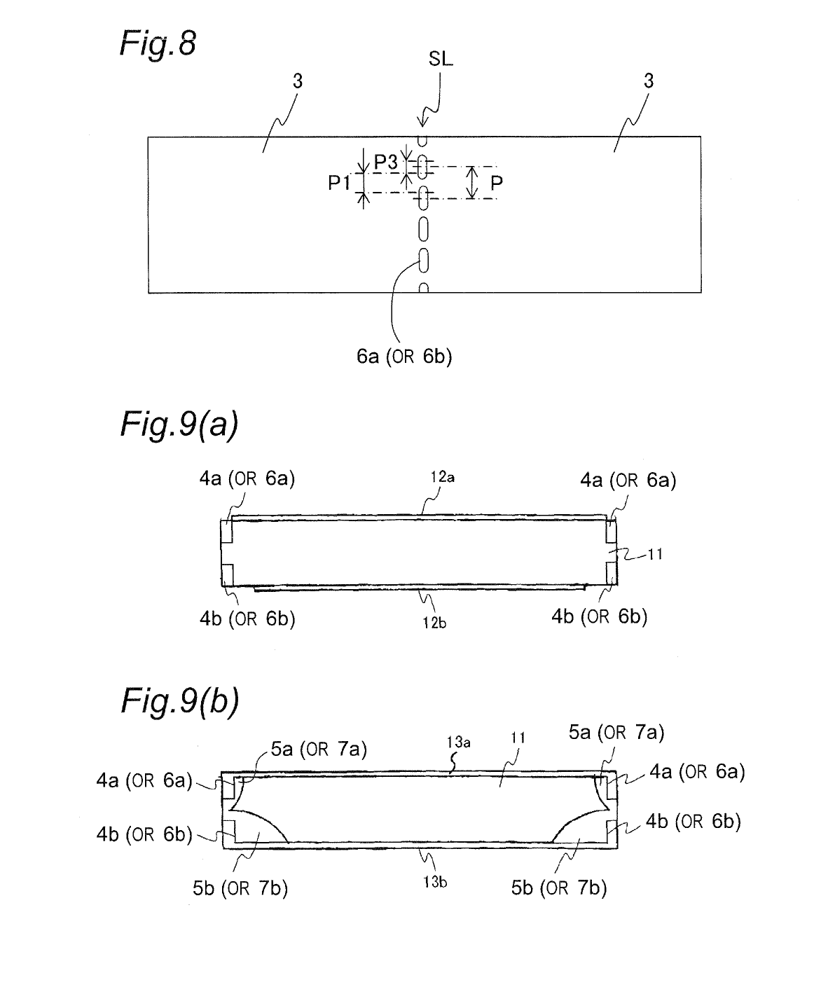

FIG. 8 is an enlarged plan view of two adjacent chips in a semiconductor wafer as a semiconductor element substrate 1B of Embodiment 3 of the invention.

In FIG. 8 and FIG. 3, the scribe line SL is formed between the semiconductor chips 3 serving as the two adjacent chips. Oval holes 6a and 6b having a predetermined depth are formed at a predetermined pitch in line in a dot shape (in a discontinuous manner) on both surfaces of the wafer along the scribe line SL. A diameter of each circle of both ends of the oval holes 6a and 6b is equal to a dicing width. The pitches of the oval holes 6a and 6b are respectively set to be equal. The adjacent semiconductor chips 3 are connected by a portion between the oval holes 6a which are adjacent on the front surface and a portion between the oval holes 6b which are adjacent on the rear surface. Thus, a configuration resistant to wafer cracks due to stress is provided. Since the oval holes 6a and 6b having the predetermined depth are formed linearly in the dot shape on the both surfaces of the wafer in this manner, each of the oval holes 6a and 6b on the both surface sides reaches a vicinity of a deep center position of wafer thickness, so that a diffusion time to a given region in which isolation diffusion layers 7a and 7b used for element isolation are connected is shortened significantly.

The respective isolation diffusion layers 7a and 7b are thermally diffused by heating processing after, for example, a P-type impurity is ion-implanted from three directions of a front surface of a silicon substrate of the semiconductor wafer, and a side wall and a bottom surface of each of the oval holes 6a and 6b, so that in a relatively short time, through the oval holes 6a and 6b on the both surface sides, the isolation diffusion layers 7a and 7b are overlapped with each other between adjacent front and back holes and between adjacent upper and lower holes, and element isolation is carried out more reliably.

The isolation diffusion layers 7a and 7b are respectively diffused, for example, with a diameter R (both-end sides of an oval in a plan view) with each of the oval holes 6a and 6b arranged in line on the both surface sides as a center. Accordingly, it is desired that a distance obtained by subtracting a distance P3 and diameters of both ends from a center-to-center distance between the circular holes 6a or 6b (pitch) and a distance in a depth direction between the respective bottom surfaces of the oval holes 6a and 6b (P2) are equal. In a case where the distance obtained by subtracting the distance P3 and diameters of both ends from the center-to-center distance (pitch) between the circular holes 6a or 6b and the distance in a depth direction between the respective bottom surfaces of the oval holes 6a and 6b (P2) are equal, when the isolation diffusion layers 7a and 7b spread from the oval holes 6a and 6b, the isolation diffusion layers 7a and 7b reach each other from front and back and from up and down and are then overlapped with each other with the almost same extent at the almost same time, thus making it possible to set the diffusion time efficiently.

Thus, according to Embodiment 3, the plurality of oval holes 6a and 6b are respectively provided on the both surfaces of the wafer side by side discontinuously and intermittently along the scribe line SL between the semiconductor devices including the semiconductor elements which are adjacent to each other, and the isolation diffusion layers 7a and 7b in a single conductivity type (here, P-type) used for element isolation are respectively formed around the plurality of oval holes 6a and 6b so as to reach the center portion in the depth direction from the both surfaces of the wafer and to be at least partially overlapped with each other between the adjacent holes and between the upper and lower bottom surfaces.

Thereby, the isolation diffusion layers 7a and 7b are respectively formed from the both surface sides through the oval holes 6a and 6b having the predetermined depth on the both surfaces of the wafer, so that it is possible to obtain the semiconductor wafer as the semiconductor element substrate 1B of Embodiment 3 capable of significantly shortening the diffusion time when forming the isolation regions without deteriorating strength against wafer cracks. It is possible to easily cut the semiconductor wafer along the scribe line SL from the oval holes 6a and 6b in the dot shape to divide into a plurality of semiconductor element chips.

Note that, Embodiment 3 describes the case where at positions of element isolation in the scribe line SL, the oval holes 6a and 6b having the predetermined depth are formed on the both surfaces of the wafer at the predetermined pitch in line in the dot shape (in a discontinuous manner), and then, the isolation diffusion layers 7a and 7b are respectively formed from the both surface sides through the oval holes 6a and 6b having the predetermined depth on the both surfaces of the wafer, but without limitation thereto, it may be configured such that at positions of element isolation in the scribe line SL, the oval holes 6a having the predetermined depth are formed at the predetermined pitch in line in the dot shape (in a discontinuous manner) only on the front surface (one side) of the wafer, and then, the isolation diffusion layers 7a are formed from the both surface sides of the wafer through only the oval holes 6a having the predetermined depth on the front surface side. In this case, the isolation diffusion layers 7b are not provided deeply as much as the oval holes 6b having the predetermined depth on the rear surface side are not involved, and the entire diffusion time becomes long for providing element isolation layers, but the strength against wafer cracks is further kept, for example, when a semiconductor wafer is thin.

Note that, though description has been given for the case where the circular holes 4a and 4b are formed on the both surfaces of the semiconductor wafer in Embodiments 1 and 2 above and the oval holes 6a and 6b are formed on the both surfaces of the semiconductor wafer in Embodiment 3, and impurity ions are implanted therethrough so that the isolation diffusion layers 5a and 5b and the isolation diffusion layers 7a and 7b are formed, as shapes of the holes in a plan view, in addition to the circular holes 4a and 4b and the oval holes 6a and 6b, holes or long holes in a rectangular shape (having bottoms) such as a square or an oblong in a plan view may be used, or they may be formed in a dot shape side by side linearly and discontinuously.

Note that, Embodiment 3 describes the case where the respective pitches of the oval holes 6a and 6b which are formed on the both surfaces of the semiconductor wafer (the oval holes 6a and 6b should be represented as having holes which are long in a horizontal direction compared to the illustrated ones, but the circular holes 4a and 4b are illustrated as representatives in FIG. 4(a)) are not shifted between an upper part and a lower part as illustrated in FIG. 4(a), but without limitation thereto, as Embodiment 2 above, the respective pitches of the oval holes 6a and 6b formed on the both surfaces of the semiconductor wafer (the oval holes 6a and 6b should be represented as having holes which are long in a horizontal direction compared to the illustrated ones, but the circular holes 4a and 4b are illustrated as representatives in FIG. 4(b)) may be shifted to each other successively (for example, shifted by half a pitch) as illustrated in FIG. 4(b).

That is, it may be configured such that as illustrated in FIG. 4(b), the pitch of the two adjacent oval holes 6a and 6a taken from the front surface of the semiconductor wafer and the pitch of the two adjacent oval holes 6b and 6b facing thereto, which are taken from the rear surface, are shifted, for example, by half a pitch, and a part of the bottom surface of the oval hole 6b is positioned at a position directly under a position between the respective bottom surfaces of the oval holes 6a and 6a which are horizontally arrayed, in which an amount of the shift may not be half a pitch.

### Embodiment 4

Though the semiconductor element substrate and the method for producing the same are described in Embodiments 1 to 3 above, a thyristor element substrate and a method for producing the same are specifically described in Embodiment 4.

A thyristor element is a switching element and examples thereof include an SCR and a triac. The SCR is a uni-directional element and has three terminals of a cathode (K), an anode (A) and a gate of a control terminal (G). A circuit formed of a load and a power source is connected between the anode (A) and the cathode (K) and switching-on control is able to be performed by a gate voltage to the gate (G).

On the other hand, the triac is a bi-directional element, and has three terminals of a drive terminal (front surface electrode T1), a drive terminal (rear surface electrode T2) and a gate of a control terminal (G). A circuit formed of a load and a power source is connected between the drive terminal (front surface electrode T1) and the drive terminal (rear surface electrode T2) and switching-on control is able to be performed by a control voltage to the gate (G).

In short, as long as voltage is applied between the drive terminal (front surface electrode T1) and the drive terminal (rear surface electrode T2), the triac allows switching-on control by the gate voltage regardless of a polarity thereof. The triac is turned off when a current is equal to or less than a holding current.

FIG. 9(a) and FIG. 9(b) are vertical cross-sectional views illustrating isolation steps of a process for producing a chip in the semiconductor element substrate of Embodiment 4 of the invention.

The isolation steps in the method for producing the semiconductor element substrate of Embodiment 4 have a hole formation step of, on the both surfaces of a semiconductor wafer 11 as an N-type substrate, forming the circular holes 4a and 4b of Embodiments 1 and 2 above (or the oval holes 6a and 6b of Embodiment 3 above) from the both surfaces of the wafer by performing etching (or laser processing) with a mask for holes by using a photolithography technique and forming first oxide insulating films 12a and 12b in a predetermined shape as illustrated in FIG. 9(a); an impurity ion implantation step of implanting boron at a predetermined concentration as impurity ions from the both surfaces of the wafer through the circular holes 4a and 4b of Embodiments 1 and 2 above (or the oval holes 6a and 6b of Embodiment 3 above) and respective openings of the first oxide insulating films 12a and 12b to form a P-type impurity region as illustrated in FIG. 9(b); and an isolation diffusion step of forming second oxide insulating films 13a and 13b instead of the first oxide insulating films 12a and 12b on the both surfaces of the semiconductor wafer 11, then, diffusing the P-type impurity region by performing heating processing at 1250 degrees centigrade and for 187.5 hours under conditions that wafer thickness is 245 μm and hole depth is 37.3 μm, and forming the isolation diffusion layers 5a and 5b of Embodiments 1 and 2 above (or the isolation diffusion layers 7a and 7b of Embodiment 3 above).

The solation diffusion layers 5a and 5b of Embodiments 1 and 2 above (or the isolation diffusion layers 7a and 7b of Embodiment 3 above) are formed around each element region of the semiconductor wafer 11 as the N-type substrate. A semiconductor element is formed in a semiconductor chip region (element region) surrounded by the isolation diffusion layers 5a and 5b of Embodiments 1 and 2 above (or the isolation diffusion layers 7a and 7b of Embodiment 3 above).

In short, the method for producing the semiconductor element substrate 1, 1A or 1B has a hole formation step of forming a plurality of holes, which are discontinuous along the scribe line SL, for example, the circular holes 4a and 4b of Embodiments 1 and 2 above (or the oval holes 6a and 6b of Embodiment 3 above) on one surface of the wafer or on the both surfaces of the wafer; an impurity implantation step of ion-implanting an impurity from the both surfaces or one surface of the wafer through the holes to form an impurity region; an isolation diffusion step of diffusing the impurity region by heating processing and forming the isolation diffusion layers 5a and 5b of Embodiments 1 and 2 above (or the isolation diffusion layers 7a and 7b of Embodiment 3 above) as isolation diffusion layers; and a semiconductor device formation step of forming a semiconductor device (semiconductor element) for each element isolation region surrounded by the isolation diffusion layers. It is possible to obtain the semiconductor device (semiconductor element), around which the element isolation regions are formed, by cutting and dividing the thus produced semiconductor element substrate 1, 1A or 1B along the scribe line SL.

Examples of a thyristor element as the semiconductor element include an SCR and a triac, and a method for producing a triac will be described briefly here.

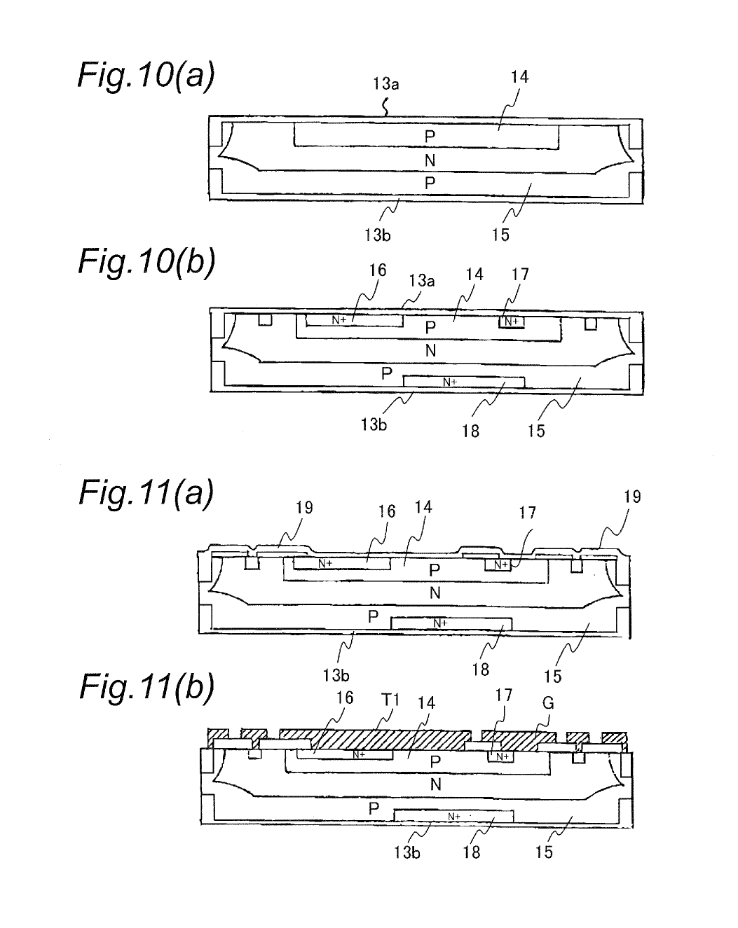

FIG. 10(a) and FIG. 10 (b) are vertical cross-sectional views illustrating boron diffusion and phosphorus diffusion steps of the process for producing a chip in the semiconductor element substrate of Embodiment 4 of the invention.

As illustrated in the boron diffusion step of FIG. 10(a), boron ions are doped to a given region on the front surface side of the semiconductor wafer to form a P-type diffusion layer 14 having a predetermined concentration and boron ions are doped entirely on the rear surface side of the semiconductor wafer to form a P-type diffusion layer 15 having a predetermined concentration.

As illustrated in the phosphorus diffusion step of FIG. 10(b), phosphorus ions are doped to a given region in the P-type diffusion layer 14 on the front surface side of the semiconductor wafer to form N-type diffusion layers 16 and 17 having a predetermined concentration so as to be separated from each other by a predetermined distance and phosphorus ions are doped to a given region in the P-type diffusion layer 15 on the rear surface side of the semiconductor wafer to form an N-type diffusion layer 18 having a predetermined concentration.

FIG. 11(a) and FIG. 11(b) are vertical cross-sectional views illustrating a film growth step by CVD and an electrode formation step of the process for producing a chip unit in the semiconductor element substrate of Embodiment 4 of the invention.

As illustrated in the CVD film growth step of FIG. 11(a), the second oxide insulating film 13a is subjected to etching processing into a predetermined shape, and then a non-doped CVD film 19 is grown.

As illustrated in the electrode formation step of FIG. 11(b), the second oxide insulating film 13a and the CVD film 19 which have predetermined thickness are subjected to etching processing into predetermined shapes to expose the front surface of the wafer, and then, metal evaporation (for example, Al evaporation) is performed thereon, and a metal evaporation film is formed on the front surface electrode T1 and a gate electrode G in predetermined shapes. The front surface electrode T1 is formed on the N-type diffusion layer 16 with electrical connection and the gate electrode G is formed on the N-type diffusion layer 17 with electrical connection, and they are separated from each other by a predetermined distance.

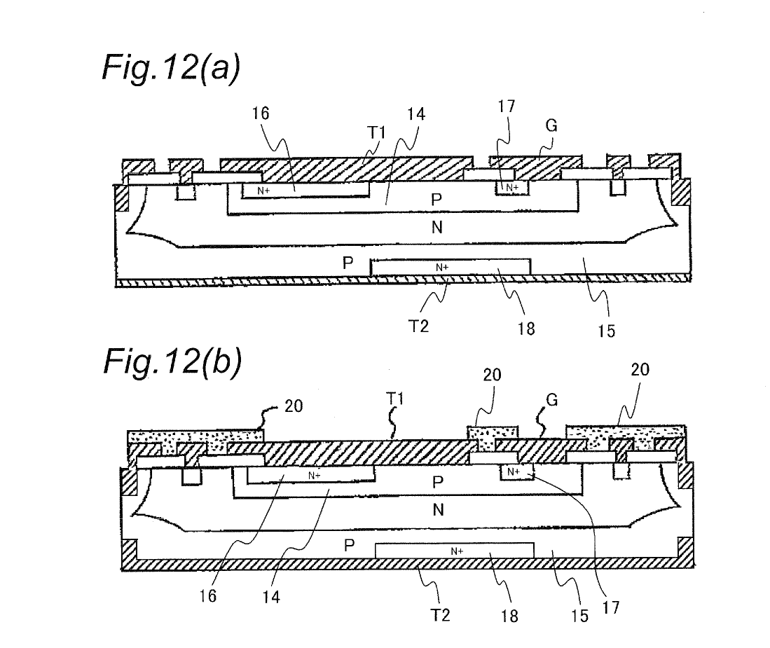

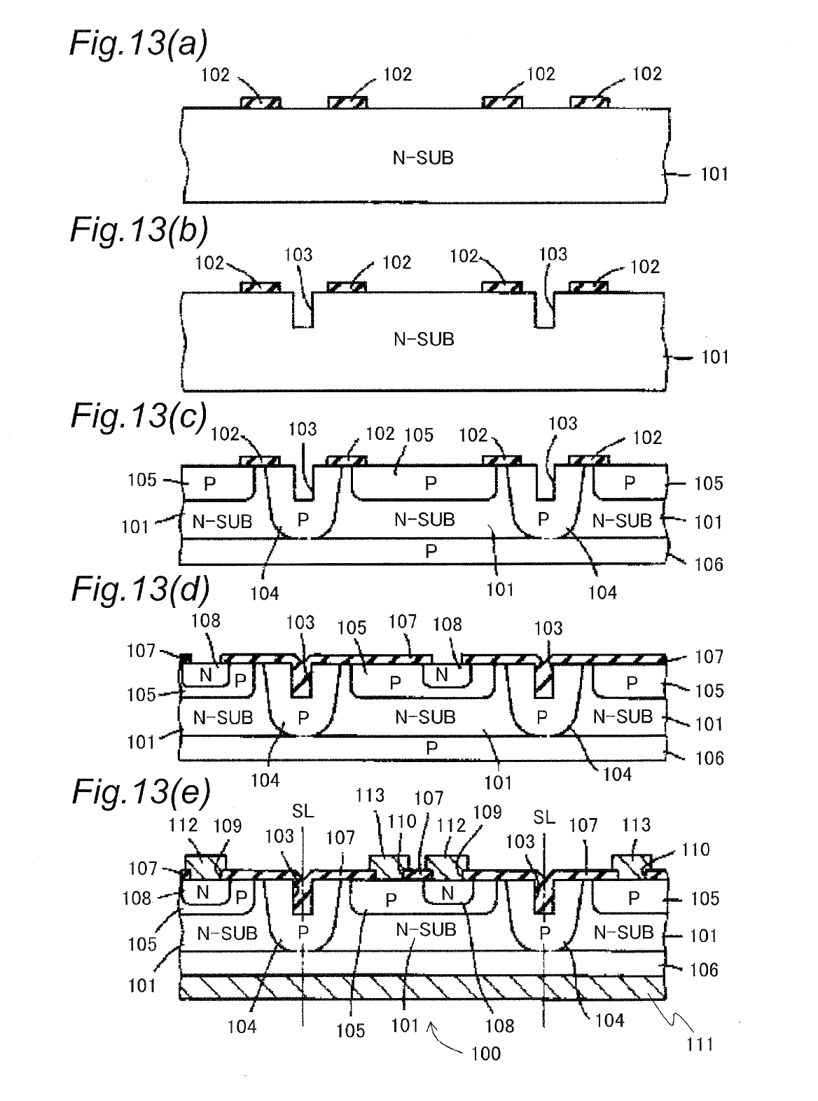

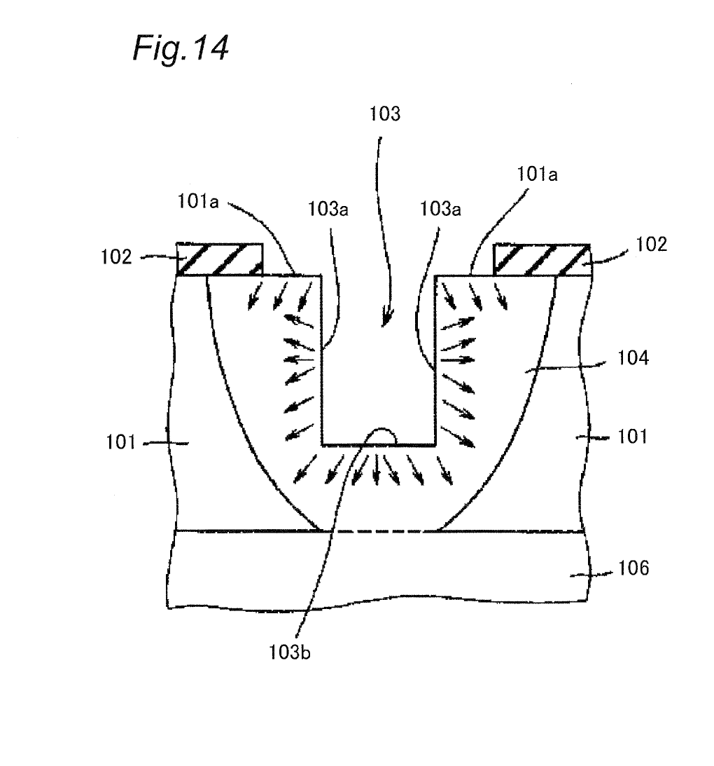

FIG. 12(a) and FIG. 12(b) are vertical cross-sectional views illustrating rear surface electrode formation and PI coat formation steps of the process for producing a chip in the semiconductor element substrate of Embodiment 4 of the invention.

As illustrated in the rear surface electrode formation step of FIG. 12(a), after the second oxide insulating film 13b on the rear surface side of the semiconductor wafer is removed, the rear surface electrode T2 is formed entirely on the rear surface side with electrical connection.

As illustrated in the PI coat formation step of FIG. 12(b), a PI coat film 20 is formed so as to provide opening over the front surface electrode T2 and the gate electrode G on the front surface side of the semiconductor wafer.

Accordingly, it is possible to produce the triac which allows switching-on control by the control voltage to the gate electrode G by connecting the circuit formed of the load and the power source between the front surface electrode T1 and the rear surface electrode T2.

The triac uses a whole thickness of the wafer. The triac has a bi-directional thyristor structure of NPNP, in which current flows in a direction of the wafer thickness (bi-direction). The triac is configured with a current path in a vertical direction (direction of the wafer thickness). Therefore, element isolation is performed between the chips in the isolation diffusion layers 5a and 5b of Embodiments 1 and 2 above (or the isolation diffusion layers 7a and 7b of Embodiment 3 above) all of which are connected in the direction of the wafer thickness at the isolation step. At the isolation step, the element isolation is performed by connecting the isolation diffusion layers with thermal diffusion of an impurity from an upper surface and a lower surface. When the isolation diffusion layers 5a and 5b of Embodiments 1 and 2 above (or the isolation diffusion layers 7a and 7b of Embodiment 3 above) are not connected between the adjacent holes or in up and down, a difficulty is caused in element performance by leakage to an adjacent element.

It takes time to diffuse the isolation diffusion layers 5a and 5b of Embodiments 1 and 2 above (or the isolation diffusion layers 7a and 7b of Embodiment 3 above) by heating processing so as to be connected vertically in the direction of the wafer thickness and a producing cost increases. At the isolation step, a thin wafer having a wafer thickness of, for example, 245 μm (wafer thickness is normally 625 μm) requires 375 hours in the high temperature atmosphere with 1250 degrees centigrade. Thereby, for example, the cost of the triac is determined. In addition, damages such as wafer cracks cause leakage.

On the other hand, according to Embodiment 4, the circular holes 4a and 4b of Embodiments 1 and 2 above (or the oval holes 6a and 6b of Embodiment 3 above) are formed from the both surfaces of the semiconductor wafer 11, boron is ion-implanted therethrough as impurity ions from the both surfaces of the wafer and a P-type impurity region is formed at a deeper position, and then, diffusion processing is performed at 1250 degrees centigrade and with a heating time almost half 370 hours to diffuse the P-type impurity region, so that the isolation diffusion layers 5a and 5b of Embodiments 1 and 2 above (or the isolation diffusion layers 7a and 7b of Embodiment 3 above) are formed in a shorter time.

Accordingly, since ion implantation is performed through the circular holes 4a and 4b in Embodiments 1 and 2 above (or the oval holes 6a and 6b of Embodiment 3 above) having a diameter of about 40 μm (dicing blade width), which are formed intermittently and linearly in the dot shape along the scribe line SL (for example, 60 μm), wafer cracks are prevented and strength of the wafer is not deteriorated compared to processing of grooves along the scribe line SL. This makes it possible to prevent leakage between elements. Further, it is possible to significantly shorten the diffusion time when forming the isolation regions.

Note that, though the invention is exemplified by the use of preferred Embodiments 1 to 4 as described above, the invention should not be interpreted solely based on Embodiments 1 to 4. It is understood that the scope of the invention should be interpreted solely based on the scope of claims. It is understood that those skilled in the art can implement equivalent scope, based on the description of the invention and common knowledge from the description of the specific preferred Embodiments 1 to 4 of the invention. It is understood that contents of any patent, any patent application and any references cited in the present specification should be incorporated by reference in the present specification in the same manner as the contents are specifically described therein.

### INDUSTRIAL APPLICABILITY

The invention is able to shorten a diffusion time when forming an isolation region without deteriorating strength against wafer cracks in a field of a semiconductor element substrate using isolation diffusion layers as an isolation technique of element isolation and a method for producing the same.

1. A semiconductor element substrate, wherein a plurality of semiconductor devices are arranged in a matrix manner, a plurality of holes are provided discontinuously along a scribe line between the semiconductor devices which are adjacent to each other, and isolation diffusion layers used for element isolation are respectively formed around the plurality of holes.

2. The semiconductor element substrate according to claim 1, wherein the plurality of holes are formed along the scribe line from both surfaces of the substrate, and the respective isolation diffusion layers in a single conductivity type used for the element isolation are formed so as to reach a center portion in a depth direction from the both surfaces of the substrate and to be at least partially overlapped with each other between adjacent holes and vertically.

3. The semiconductor element substrate according to claim 2, wherein a plurality of holes aligned with a pitch in the front surface of the substrate are shifted with respect to a plurality of holes formed in the rear surface of the substrate.

4. The semiconductor element substrate according to claim 2, wherein a distance of a connected portion between the adjacent holes which are adjacent in a direction of the scribe line and a distance in a depth direction between a bottom surface of each of the holes in the front surface of the substrate and a bottom surface of each of the holes in the rear surface of the substrate are the same.

5. A method for producing a semiconductor element substrate, comprising: a hole formation step of forming a plurality of holes, which are discontinuous, along a scribe line on one surface or both surfaces of the substrate; an impurity implantation step of ion-implanting an impurity from both surfaces of a wafer through the holes to form an impurity region; an isolation diffusion step of diffusing the impurity by heating processing to form isolation diffusion layers; and a semiconductor device formation step of forming a semiconductor device for each element isolation region surrounded by the isolation diffusion layers.
